(19) United States
(12) Patent Application Publication
(10) Pub. No.: US 2011/0205721 A1
(43) Pub. Date: Aug. 25, 2011

(54) RESIN COMPOSITION, RESIN SHEET, PREPREG, LAMINATE, MULTILAYER PRINTED WIRING BOARD, AND SEMICONDUCTOR DEVICE

(76) Inventor: Tadasuke Endo, Tokyo (JP)

(21) Appl. No.: 13/126,093

(22) PCT Filed: Oct. 27, 2009
(86) PCT No.: PCT/JP2009/068408

§ 371 Date: Apr. 26, 2011

(30) Foreign Application Priority Data
Oct. 29, 2008 (JP) 2008-277702

(51) Int. Cl. H05K 1/18; B32B 27/38; B32B 27/34; B32B 7/00; C08L 63/00; C08K 3/22; C08K 3/34; C08L 77/10; C08L 79/00; H05K 1/03; B32B 37/06; B32B 37/10

(52) U.S. Cl. 361/783; 428/413; 428/414; 428/336; 428/141; 428/416; 523/400; 523/457; 523/466; 174/258; 156/308.2

(57) ABSTRACT

Disclosed is a resin composition having a low thermal expansion coefficient and a high glass transition temperature used for the insulating layer of a multilayer printed wiring board, capable of forming an insulating layer having fine roughened shapes and imparting sufficient plating peel strength. Also disclosed are a resin sheet, a prepreg, a laminate, a multilayer printed wiring board and a semiconductor device, all of which comprising the resin composition. The resin composition is a resin composition comprising (A) an epoxy resin, (B) a cyanate ester resin, (C) an aromatic polyamide resin containing at least one hydroxyl group and (D) an inorganic filler, as essential components.

### TECHNICAL FIELD

The present invention relates to a resin composition, a resin sheet, a prepreg, a laminate, a multilayer printed wiring board, and a semiconductor device.

### BACKGROUND ART

In recent years, with growing demand for higher function of electronics, high-density integration and high-density mounting of electronic components have been developed. Hence, printed wiring boards capable of high-density mounting and so on used for the electronic components have been developed in miniaturization and high density than ever before. To increase the density on the printed wiring boards, build-up multilayer printed wiring boards have been widely employed (for example, see Patent Literature 1).

In build-up multilayer printed wiring boards, thermosetting resin compositions are generally used as insulating layers, and resin compositions having a low thermal expansion coefficient and a high glass transition temperature are required for the insulating layers considering reliability and so on (for example, see Patent Literature 2).

However, although the selection of resins or the method for filling high amount of inorganic fillers can decrease the thermal expansion coefficient and increase the glass transition temperature, such resin compositions are not applicable for multilayer printed wiring boards requiring forming fine wiring circuits with further narrow breadth of conducting circuits or breadth between conducting circuits formed on the printed wiring boards.

The reason thereof is that the contact area between the conducting circuit and the insulating layer is decreased in the case that the breadth of the conducting circuit narrows, particularly in the case of a size called a fine wiring circuit; therefore, the adhesion of the conducting circuit to the insulating layer decreases, causing the conducting circuit to peel, which is called plating peeling off.

By forming fine roughened shapes on a surface of the insulating layer comprising a resin composition, and by forming a fine wiring circuit on the insulating layer having such fine roughened shapes, it is possible to increase the adhesion of the fine wiring circuit. To sufficiently increase the adhesion of the fine wiring circuit, however, it is necessary to increase the surface roughness of the insulating layer. If the surface roughness of the insulating layer is increased too much, when forming a conducting circuit pattern on the surface of the insulating layer surface by a photo process, it is hard to focus upon exposure to light; thus, it is difficult to accurately form the pattern.

Therefore, there is a limit on the method for increasing plating peel strength between the conducting circuit and the insulating layer by forming fine roughened shapes.

In order to form fine roughened shapes and obtain sufficient plating peel strength, an adhesion assistant material containing rubber particles (for example, see Patent Literature 3) and a resin composition comprising a polyimide resin (for example, see Patent Literature 4) have been studied for forming an adhesive layer on the surface of the insulating layer. However, there is no art which is able to form fine roughened shapes on the surface of the insulating layer and which has sufficient plating peel strength.

### CITATION LIST

### Patent Literature

[Patent Literature 1] Japanese Patent Application Laid-Open (JP-A) No. H07-106767
[Patent Literature 2] JP-A No. 2006-191150
[Patent Literature 3] JP-A No. 2006-159900
[Patent Literature 4] JP-A No. 2006-196863

### SUMMARY OF INVENTION

### Technical Problem

The present invention provides a resin composition having a low thermal expansion coefficient and a high glass transition temperature used for the insulating layer of a build-up multilayer printed wiring board, capable of forming an insulating layer having fine roughened shapes and imparting sufficient plating peel strength. The present invention also provides a resin sheet, a prepreg, a laminate, a multilayer printed wiring board and a semiconductor device, all of which comprising the resin composition.

### Solution to Problem

The above object can be attained by the following [1] to [30].

[1] A resin composition comprising (A) an epoxy resin, (B) a cyanate ester resin, (C) an aromatic polyamide resin containing at least one hydroxyl group and (D) an inorganic filler, as essential components.

[2] The resin composition according to the above [1], wherein an equivalent ratio of an active hydrogen equivalent of the aromatic polyamide resin (C) containing at least one hydroxyl group is 0.02 or more and 0.2 or less with respect to an epoxy equivalent of the epoxy resin (A).

[3] The resin composition according to the above [1], wherein the aromatic polyamide resin (C) containing at least one hydroxyl group contains a segment comprising a repeating unit having a diene skeleton and four or more carbons.

[4] The resin composition according to the above [1], wherein a content of the aromatic polyamide resin (C) containing at least one hydroxyl group is 20 to 70% by weight of a total content of the resin composition.

[5] The resin composition according to the above [1], wherein the cyanate ester resin (B) is a novolac type cyanate ester resin.

[6] The resin composition according to the above [1], wherein the inorganic filler (D) is one or more kinds selected from the group consisting of magnesium hydroxide, aluminum hydroxide, silica, talc, calcined talc and alumina.

[7] The resin composition according to the above [1], wherein the inorganic filler (D) has an average particle diameter of 5.0 μm or less.

[8] A resin sheet comprising a base material and an insulating layer on the base material, wherein the insulating layer comprises the resin composition defined by the above [1].

[9] The resin sheet according to the above [8], wherein only the insulating layer comprising the resin composition defined by the above [1] is on the base material.

[10] The resin sheet according to the above [8], wherein two or more insulating layers each comprising a resin composition are on the base material, and at least one of the insulating layers is an insulating layer comprising the resin composition defined by the above [1].

[11] The resin sheet according to the above [8], wherein a layer closest to the base material is an insulating layer comprising the resin composition defined by the above [1].

[12] The resin sheet according to the above [8], wherein the insulating layer comprising the resin composition defined by the above [1] has a thickness of 0.5 μm to 10 μm.

[13] The resin sheet according to the above [8], wherein the insulating layer comprising the resin composition defined by the above [1] has an average surface roughness of 2.0 μm or less.

[14] A prepreg with an insulating layer, wherein the insulating layer comprising the resin composition defined by the above [1] is on at least one surface of the prepreg.

[15] The prepreg with the insulating layer according to the above [14], wherein only the insulating layer comprising the resin composition defined by the above [1] is on at least one surface of the prepreg.

[16] The prepreg with the insulating layer according to the above [14], wherein one or more insulating layers each comprising a resin composition are on at least one surface of the prepreg, and at least one of the insulating layers is an insulating layer comprising the resin composition defined by the above [1].

[17] The prepreg with the insulating layer according to the above [14], wherein an outermost insulating layer with respect to the prepreg is an insulating layer comprising the resin composition defined by the above [1].

[18] The prepreg with the insulating layer according to the above [14], wherein the insulating layer comprising the resin composition defined by the above [1] has a thickness of 0.5 μm to 10 μm.

[19] A laminate comprising a cured product of a prepreg with an insulating layer, wherein one or more insulating layers each comprising a resin composition are on at least one surface of the prepreg, and at least one of the insulating layers is an insulating layer comprising the resin composition defined by the above [1].

[20] The laminate according to the above [19], wherein an outermost layer of the insulating layers is an insulating layer comprising the resin composition defined by the above [1].

[21] The laminate according to the above [19], obtained by laying the resin sheet defined by the above [8] on at least one surface of the prepreg so that the insulating layer of the resin sheet faces the prepreg, and heat-pressing them.

[22] The laminate according to the above [19], obtained by heat-pressing one or more prepregs with the insulating layer defined by the above [14].

[23] A metal foil-clad laminate comprising a cured product of a prepreg with a resin layer, wherein one or more insulating layers each comprising a resin composition are on at least one surface of the prepreg; at least one of the insulating layers is an insulating layer comprising the resin composition defined by the above [1]; and further a metal foil layer is on an outer side of the insulating layer.

[24] The metal foil-clad laminate according to the above [23], wherein an outermost layer of the insulating layers is an insulating layer comprising the resin composition defined by the above [1].

[25] The metal foil-clad laminate according to the above [23], obtained by laying a resin sheet which is the resin sheet defined by the above [8] and comprising a metal foil as the base material, on at least one surface of the prepreg so that the insulating layer of the resin sheet faces the prepreg, and followed by heat-pressing.

[26] The metal foil-clad laminate according to the above [23], obtained by laying a metal foil on at least one side of one prepreg with an insulating layer, which is the prepreg with the insulating layer defined by the above [14], or on a stack of two or more prepregs with an insulating layer, each of which is the prepreg with the insulating layer defined by the above [14], and followed by heat-pressing.

[27] A multilayer printed wiring board comprising an inner layer circuit board and one or more insulating layers each comprising a resin composition, wherein the insulating layer or insulating layers are on an inner layer circuit pattern of the inner layer circuit board, and at least one of the insulating layers is an insulating layer comprising the resin composition defined by the above [1].

[28] The multilayer printed wiring board according to the above [27], wherein, among the insulating layers, an outermost insulating layer with respect to the inner layer circuit pattern is an insulating layer comprising the resin composition defined by the above [1].

[29] The multilayer printed wiring board according to the above [27], obtained by laying the resin sheet defined by the above [8] on a surface of the inner layer circuit board, on which the inner layer circuit pattern is formed, and followed by heat-pressing.

[30] The multilayer printed wiring board according to the above [27], obtained by laying the prepreg with the insulating layer defined by the above [14] on a surface of the inner layer circuit board, on which the inner layer circuit pattern is formed, and followed by heat-pressing.

[31] A semiconductor device comprising the multilayer printed wiring board defined by the above [27] and a semiconductor element mounted on the multilayer printed wiring board.

### Advantageous Effects of Invention

When used to form the insulating layer of a build-up multilayer printed wiring board, the resin composition of the present invention forms an insulating layer having a low thermal expansion coefficient and a high glass transition temperature, and forms fine roughened shapes on the surface of the insulating layer. In addition, the insulating layer adheres to a conducting circuit with sufficient plating peel strength. Furthermore, a resin sheet, a prepreg, a laminate, a multilayer printed wiring board and a semiconductor device, all of which comprise the resin composition, are excellent in reliability.

### BRIEF DESCRIPTION OF DRAWINGS

FIG. 1 is a view schematically showing an example of a resin sheet of the present invention.

FIG. 2 is a view schematically showing a different example of the resin sheet of the present invention.

FIG. 3 is a view schematically showing a different example of the resin sheet of the present invention.

FIG. 4 is a view schematically showing an example of a prepreg with an insulating layer of the present invention.

FIG. 5 is a view schematically showing a different example of the prepreg with the insulating layer of the present invention.

FIG. 6 is a view schematically showing a different example of the prepreg with the insulating layer of the present invention.

FIG. 7 is a view schematically showing a different example of the prepreg with the insulating layer of the present invention.

FIG. 8 is a view schematically showing an example of a laminate of the present invention.

FIG. 9 is a view schematically showing a different example of the laminate of the present invention.

FIG. 10 is a procedure showing an example of a method for producing a multilayer printed circuit board of the present invention.

### REFERENCE SIGNS LIST

1: Base material
2a, 2b: Insulating layer comprising resin composition of the present invention
3a, 3b and 3c: Other insulating layers
4: Prepreg
5: Metal foil
6: Film
7: Core substrate
8: Inner layer circuit

### DESCRIPTION OF EMBODIMENTS

Hereinafter, a resin composition, resin sheet, prepreg, laminate, multilayer printed wiring board and semiconductor device of the present invention will be described.

Firstly, the resin composition of the present invention will be described.

The resin composition used in the present invention is a resin composition comprising (A) an epoxy resin, (B) a cyanate ester resin, (C) an aromatic polyamide resin containing at least one hydroxyl group and (D) an inorganic filler, as essential components. Thereby, the resin composition has a low thermal expansion coefficient and a high heat resistance, and is able to form an insulating layer having fine roughened shapes on a surface thereof and thus having high adhesion (plating peel strength) to conducting circuits.

The epoxy resin (A) is not particularly limited. The examples include: novolac type epoxy resins such as phenol novolac type epoxy resins, cresol novolac type epoxy resins, biphenyl aralkyl type novolac epoxy resins and dicyclobentadiene type novolac epoxy resins; bisphenol type epoxy resins such as bisphenol A epoxy resins, bisphenol F epoxy resins and bisphenol S epoxy resins; and bifunctional epoxy resins such as biphenyl type bifunctional epoxy resins, naphthalene type bifunctional epoxy resins and anthracene type (including derivatives) bifunctional epoxy resins. Among them, novolac type epoxy resins are preferable from the viewpoint of heat resistance and thermal expansion, and aralkyl type novolac type epoxy resins are more preferable from the viewpoint of water absorption and adhesion.

A content of the epoxy resin (A) is not particularly limited, and is generally 10% by weight to 70% by weight of the resin composition.

The cyanate ester resin (B) imparts a low thermal expansion coefficient and a heat resistance to the resin composition, which are not achieved only by the epoxy resin. It is not preferable that the resin composition does not contain the cyanate ester resin (B), since the resin composition has a high thermal expansion coefficient and a low glass transition temperature in this case. The cyanate ester resin (B) can be obtained by, for example, reacting a cyanogen halide compound with a phenol and, as needed, prepolymerizing the reactant by a method such as heating.

The cyanate ester resin (B) is not particularly limited. The examples include: novolac type cyanate resins such as phenol novolac type cyanate resins, cresol novolac type cyanate resins, phenol aralkyl type novolac cyanate resins and dicyclopentadiene type novolac cyanate resins; and bisphenol type cyanate resins such as bisphenol A type cyanate resins, bisphenol E type cyanate resins and tetramethyl bisphenol F type cyanate resins. Among them, novolac type cyanate resins are preferable from the viewpoint of heat resistance and thermal expansion coefficient. The above resins can be prepolymerized and used as the cyanate ester resin (B). That is, the cyanate ester resin (B) can be used alone or in combination with a cyanate resin having a different weight average molecular weight, or the cyanate resin can be used in combination with a prepolymer thereof. This prepolymer is generally obtained by, for example, trimerizing the cyanate resin by a heating reaction or the like, and it is preferably used to control formability and flowability of the resin composition.

A content of the cyanate ester resin (B) is not particularly limited, and is generally 5% by weight to 65% by weight of the resin composition.

The aromatic polyamide resin (C) containing at least one hydroxyl group is not particularly limited. It contains an aromatic amide structure in a resin skeleton thereof, thereby providing high adhesion to conducting circuits. By further containing a hydroxyl group, the aromatic polyamide resin can form a cross-linked structure with the epoxy resin, so that the resin composition can be a cured product with excellent physical mechanical properties.

More preferably, the aromatic polyamide resin (C) containing at least one hydroxyl group contains a segment comprising a repeating unit having a diene skeleton and four or more carbons. By containing the diene skeleton which is likely to be roughened, the resin composition can be selectively roughened on a microscopic scale, thereby forming fine roughened shapes on the surface of the insulating layer comprising the resin composition.

The aromatic polyamide resin (C) containing at least one hydroxyl group can be synthesized by the methods disclosed in Japanese patent Nos. 2,969,585 and 1,957,919, for example. More specifically, it can be obtained by condensation of an aromatic diamine material with a hydroxyl group-containing aromatic dicarboxylic acid material or, in some cases, with an aromatic dicarboxylic acid material containing no hydroxyl group.

Also, the aromatic polyamide resin containing the segment comprising a repeating unit having the diene skeleton and four or more carbons (C′) can be synthesized by reaction of a hydroxyl group-containing aromatic polyamide resin, which is obtained in the same manner as the above, with a butadiene polymer or acrylonitrile-butadiene copolymer. The reaction of the polyamide component with the butadiene polymer or acrylonitrile-butadiene copolymer (hereinafter referred to as “diene skeleton segment component”) is condensation of a hydroxyl group-containing aromatic polyamide having amino groups at both terminals thereof, which is obtained from an aromatic diamine and an aromatic dicarboxylic acid, the aromatic diamine being in an excess amount than that of the aromatic dicarboxylic acid, with a diene skeleton segment component having carboxylic acids at both terminals thereof. Or the reaction of the polyamide component with the diene skeleton segment component is condensation of a hydroxyl group-containing aromatic polyamide having carboxylic acids at both terminals thereof, which is obtained from an aromatic dicarboxylic acid and an aromatic diamine, the aromatic dicarboxylic acid being in an excess amount than that of the aromatic diamine, with a diene skeleton segment component having amines at both terminals thereof.

The condensation reaction of the aromatic diamine material with the hydroxyl group-containing aromatic dicarboxylic acid material or, in some cases, with the aromatic dicarboxylic acid material containing no hydroxyl group, and/or the condensation reaction of the polyamide component with the diene skeleton segment component having carboxylic acids or amines at both terminals thereof, can be performed by using a phosphorous condensing agent in the presence of a pyridine derivative. In addition, an organic solvent can be used in the condensation reaction and in this case, the molecular weight is increased by addition of an inorganic salt such as a lithium chloride or calcium chloride. As the phosphorous condensing agent, phosphite is preferable. According to this production method, the hydroxyl group-containing aromatic polyamide resin can be easily produced without protecting the hydroxyl group being a functional group, and also without the reaction of the hydroxyl group with other reactive group such as a carboxyl group or amino group. In addition, the production method is advantageous in that high temperature is not needed upon polycondensation, that is, polycondensation is possible at about 150° C. or less, so that it is possible to protect a double bond in the diene skeleton segment component and easy to produce a diene skeleton segment-containing polyamide resin.

Hereinafter, there will be described in detail a method for synthesizing the hydroxyl group-containing aromatic polyamide segment contained in the hydroxyl group-containing aromatic polyamide resin and the hydroxyl group- and diene skeleton segment-containing polyamide resin used in the present invention. Examples of the aromatic diamine used for the synthesis include: phenylenediamine derivatives such as m-phenylenediamine, p-phenylenediamine and m-tolylenediamine; diaminodiphenyl ether derivatives such as 4,4′-diaminodiphenyl ether, 3,3′-dimethyl-4,4′-diaminodiphenyl ether and 3,4′-diaminodiphenyl ether; diaminodiphenyl thioether derivatives such as 4,4′-diaminodiphenyl thioether, 3,3′-dimethyl-4,4′-diaminodiphenyl thioether, 3,3′-diethoxy-4,4′-diaminodiphenyl thioether, 3,3′-diaminodiphenyl thioether and 3,3′-dimethoxy-4,4′-diaminodiphenyl thioether; diaminobenzophenone derivatives such as 4,4′-diaminobenzophenone and 3,3′-dimethyl-4,4′-diaminobenzophenone; diaminodiphenyl sulfone derivatives such as 4,4′-diaminodiphenyl sulfoxide and 4,4′-diaminodiphenyl sulfone; benzidine derivatives such as benzidine, 3,3′-dimethyl benzidine, 3,3′-dimethoxy benzidine and 3,3′-diaminobiphenyl; xylylenediamine derivatives such as p-xylylenediamine, m-xylylenediamine and o-xylylenediamine; and diaminodiphenyl methane derivatives such as 4,4′-diaminodiphenyl methane, 3,3′-diaminodiphenyl methane, 4,4′-diamino-3,3′-dimethyldiphenyl methane, 4,4′-diamino-3,3′-diethyldiphenyl methane, 4,4′-diamino-3,3′,5,5′-tetramethyldiphenyl methane and 4,4′-diamino-3,3′,5,5′-tetraethyldiphenyl methane.

Also, aromatic dicarboxylic acids can be used as the hydroxyl group-containing aromatic dicarboxylic acid without any particular limitation, as long as they have a structure in which an aromatic ring has two carboxylic acids and one or more hydroxyl groups. The examples include dicarboxylic acids in which the benzene ring has one hydroxyl group and two carboxylic acids such as 5-hydroxyisophthalic acid, 4-hydroxyisophthalic acid, 2-hydroxyisophthalic acid, 3-hydroxyisophthalic acid and 2-hydroxyterephtalic acid.

The diene skeleton segment component for introducing the diene skeleton segment of the hydroxyl group- and diene skeleton segment-containing polyamide resin is not particularly limited as long as it is a butadiene polymer having the structure represented by the following formula (1-1) or an acrylonitrile-butadiene copolymer represented by the following formula (1-2):

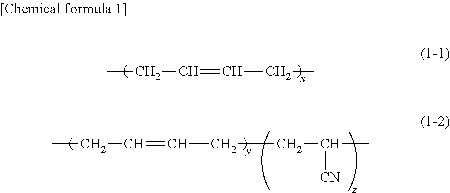

wherein each of x, y and z is a mean value; x represents a positive number of 5 to 200; y and z meet 0<z/(y+z)<0.10; and y+z is a positive number of 10 to 200.

As the diene skeleton segment component having carboxylic acids or amines at both terminals thereof, a polybutadiene having carboxylic acids at both terminals thereof (product name: Hycar CTB; manufactured by: Ube Industries, Ltd.) or a butadiene-acrylonitrile copolymer having carboxylic acids at both terminals thereof (product name: Hycar CTBN; manufactured by: Ube Industries, Ltd.) is preferable. A used amount thereof is 20 to 200% by weight, and preferably 100% by weight, with respect to the hydroxyl group-containing aromatic polyamide segment supposed. After the synthesis of the hydroxyl group-containing aromatic polyamide segment, the diene skeleton segment component having carboxylic acids at both terminals thereof is added to the reaction solution, thereby obtaining a hydroxyl group- and diene skeleton segment-containing polyamide. At this time, it is necessary to use the diene skeleton segment component considering the molar ratio of the carboxylic acids or amines at both terminals of the diene skeleton segment component and those of the hydroxyl group-containing aromatic polyamide segment.

Commercial products of the hydroxyl group- and diene skeleton segment-containing polyamide resin are KAYAFLEX BPAM01 (manufactured by: Nippon Kayaku Co., Ltd.), KAYAFLEX BPAM155 (manufactured by: Nippon Kayaku Co., Ltd.), etc. By using any of the above products, in a desmear process of the production of a multilayer printed wiring board using the resin sheet or prepreg of the present invention, the aromatic polyamide resin (C) containing at least one hydroxyl group is selectively roughened on a microscopic scale, thereby forming fine roughened shapes on the surface of the insulating layer comprising the resin composition. In addition, by imparting appropriate flexibility to the insulating layer, the adhesion of the same to conducting circuits is increased.

The aromatic polyamide resin (C) containing at least one hydroxyl group has a weight average molecular weight (Mw) of preferably 2.0×10⁵ or less. Thereby, the resin composition is provided with adhesion to copper. If the weight average molecular weight (Mw) is higher than 2.0×10⁵, upon the production of a resin sheet or prepreg from the resin composition, the resin sheet or prepreg can have low flowability, which can result in a failure to perform press molding or circuit embedding, or a deterioration in solvent solubility.

The aromatic polyamide resin (C) containing at least one hydroxyl group can cause a curing reaction with the epoxy resin (A) due to containing the hydroxyl group.

An equivalent ratio of an active hydrogen equivalent of the aromatic polyamide resin (C) containing at least one hydroxyl group is preferably 0.02 or more and 0.2 or less with respect to an epoxy equivalent of the epoxy resin (A). If the equivalent ratio exceeds the upper limit, the aromatic polyamide resin (C) containing at least one hydroxyl group cannot be sufficiently crosslinked with the epoxy resin, so that there can be a decrease in heat resistance. If the equivalent ratio is less than the lower limit, there can be an excessive increase in curing reactivity, so that the resin sheet or prepreg can have low flowability or press formability.

According to a general method for measuring active hydrogen of a phenol resin or the like, an active hydrogen equivalent of the resin is determined by: acetylizing the resin with triphenylphosphine, acetic anhydride and pyridine; hydrolyzing residual acetic anhydride with water; and then titrating free acetic acid with KOH by means of a potentiometric titrator.

In the present invention, the active hydrogen equivalent of the aromatic polyamide resin can be measured by the above general method. However, if the aromatic polyamide resin has poor solubility in solvents and causes the acetylated compound to precipitate and thus makes the measurement by titration impossible or inaccurate, a theoretical value of the active hydrogen equivalent can be calculated from the amount of the materials used.

A content of the aromatic polyamide resin (C) containing at least one hydroxyl group is not particularly limited, and is preferably 10% by weight to 80% by weight of the resin composition. If the content is less than the lower limit, there can be a decrease in peeling strength. If the content exceeds the upper limit, there can be a decrease in heat resistance and an increase in thermal expansion coefficient. A ratio of the content in the resin composition is a ratio on the solid content basis, that is, a ratio when the total amount of the components (excluding solvent) is 100% by weight.

The inorganic filler (D) is not particularly limited, and the examples include: silicate salts such as talc, calcined talc, calcined clay, uncalcined clay, mica and glass; oxides such as titanium oxide, alumina, silica and fused silica; carbonates such as calcium carbonate, magnesium carbonate and hydrotalcite; hydroxides such as aluminum hydroxide, magnesium hydroxide and calcium hydroxide; sulfates and sulfites such as barium sulfate, calcium sulfate and calcium sulfite; borates such as zinc borate, barium metaborate, aluminum borate, calcium borate and sodium borate; nitrides such as aluminum nitride, boron nitride, silicon nitride and carbon nitride; and titanates such as strontium titanate and barium titanate. As the inorganic filler, they can be used alone or in combination of two or more kinds. Among the above, magnesium hydroxide, aluminum hydroxide, silica, fused silica, talc, calcined talc and alumina are preferable. From the viewpoint of excellent low-thermal expansion characteristics, fused silica is particularly preferable.

A content of the inorganic filler (D) is not particularly limited, and is generally 2% by weight to 35% by weight of the resin composition.

A shape of the inorganic filler (D) can be a fractured shape, a spherical shape, etc., and it is selected according to the intended use. For example, to allow the inorganic filler to penetrate a base material (e.g., glass fiber) upon the production of a prepreg, it is necessary to decrease the melting viscosity of the resin composition to ensure penetration; therefore, the shape is preferably spherical. The shape of the inorganic filler can be selected according to the intended use/purpose of the resin composition.

A particle diameter of the inorganic filler (D) is not particularly limited, and it can be selected according to the intended use/purpose of the resin composition. The inorganic filler (D) preferably has an average particle diameter of 5.0 μm or less, more preferably 1.0 μm or less. If the average particle diameter exceeds 5.0 μm, in the desmear process of the production of a multilayer printed wiring board using the resin sheet or prepreg comprising the resin composition, a degree of roughness of the insulating layer can be increased, or the insulating layer cannot have smooth surface. The average particle diameter can be determined by, for example, measuring a weight average particle diameter with a particle size analyzer (product name: SALD-7000; manufactured by: Shimadzu Corporation).

The resin composition of the present invention can contain an appropriate curing agent, as needed. A type of the curing agent is not particularly limited, and the examples include phenol resins, amine compounds such as primary, secondary and tertiary amines, dicyandiamide compounds and imidazole compounds. Among them, imidazole compounds are particularly preferable from the viewpoint that they provide excellent curability and insulation reliability even in a small amount. Also, in the case of using an imidazole compound, it is particularly possible to obtain a laminate having a high glass transition temperature and excellent heat resistance after moisture absorption.

The imidazole compound is not particularly limited, and the examples include 2-methylimidazole, 2-phenylimidazole, 2-phenyl-4-methylimidazole, 2-ethyl-4-ethylimidazole, 1-benzyl-2-methylimidazole, 1-benzyl-2-phenylimidazole, 2-undecylimidazole, 1-cyanoethyl-2-ethyl-4-methylimidazole, 1-cyanoethyl-2-undecylimidazole, 2-phenyl-4-methyl-5-hydroxyimidazole, 2-phenyl-4,5-dihydroxyimidazole, and 2,3-dihydro-1H-pyrrolo(1,2-a)benzimidazole. The curing agent may be used alone or in combination of two or more kinds.

As needed, the resin composition can contain additives other than the above components, such as a colorant, a coupling agent, a defoaming agent, a leveling agent, an ultraviolet absorbing agent, a foaming agent, an antioxidant, a flame retardant and an ion scavenger.

Next, the resin sheet of the present invention will be described.

The resin sheet of the present invention comprises a base material and an insulating layer on the base material, wherein the insulating layer comprises the resin composition. As the base material, a metal foil or a film is suitably used; however, a material of the base material is not particularly limited.

The method for forming the insulating layer comprising an insulating resin composition on the metal foil or film is not particularly limited herein. The examples include the following: a method comprising the steps of dissolving and dispersing an insulating resin composition in a solvent or the like to prepare a resin varnish, applying the resin varnish on a base material by means of a coater selected from various kinds of coaters, and drying the same; and a method comprising the steps of spraying a resin varnish on a base material by means of a spraying apparatus and drying the same.

It is desirable that the solvent used for the resin varnish has excellent properties to dissolve the resin components of the insulating resin composition. However, a poor solvent can be used to the extent that it exerts no negative effect. Examples of the solvent having good solubility include acetone, methyl ethyl ketone, methyl isobutyl ketone, cyclohexanone, tetrahydrofuran, dimethylformamide, dimethylacetamide, dimethylsulfoxide, ethylene glycol, cellosolves and carbitols.

A solid content of the resin varnish is not particularly limited, and is preferably 10 to 70% by weight, more preferably 20 to 55% by weight.

When the resin sheet of the present invention comprises two or more insulating layers, at least one of the insulating layers is preferably an insulating layer comprising the resin composition of the present invention.

It is preferable that the resin layer comprising the resin composition of the present invention is formed directly on the metal foil or film. That is, it is preferable that the insulating layer closest to the base material of the resin sheet is the insulating layer comprising the resin composition of the present invention. Thereby, upon the production of a multilayer printed wiring board, the insulating layer comprising the resin composition of the present invention exhibits high plating peel strength with outer layer circuit conductors.

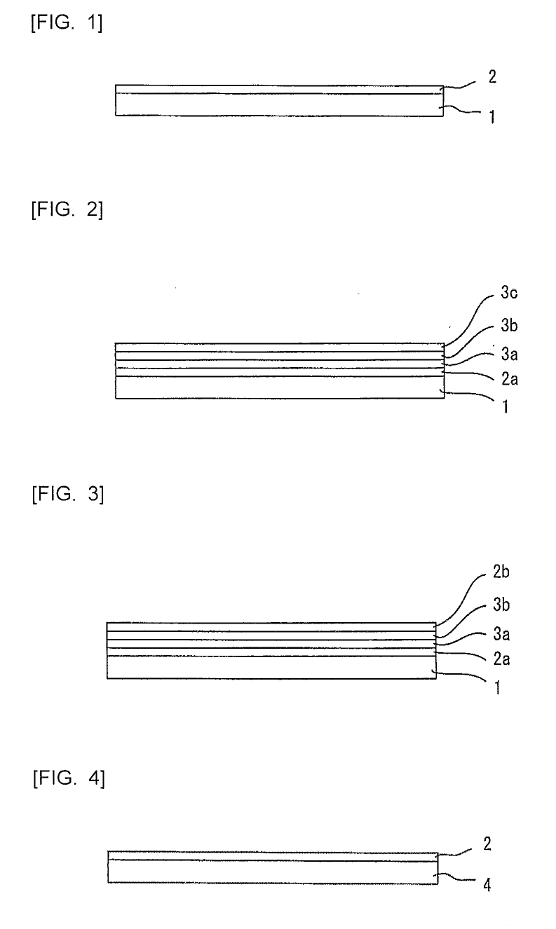

For instance, as shown in FIG. 1, an example of the case where the insulating layer closest to the base material of the resin sheet is such that only resin layer 2 comprising the resin composition of the present invention is on base material 1. Also, there may be mentioned a different example in FIG. 2 that a plurality of insulating layers each comprising a resin composition are on base material 1, and only the insulating layer closest to the base material is resin layer 2 comprising the resin composition of the present invention, while other insulating layers are resin layers 3a, 3b and 3c each comprising a resin composition which is not the resin composition of the present invention. Furthermore, there may be mentioned a different example in FIG. 3 that a plurality of insulating layers each comprising a resin composition are on base material 1, and two or more layers including insulating layer 2a which is closest to the base material (in this case, the insulating layer 2a and insulating layer 2b which are farthest from the base material) are resin layers each comprising the resin composition of the present invention, while other insulating layers are resin layers 3a and 3b each comprising a resin composition which is not the resin composition of the present invention.

The insulating layer comprising the resin composition of the present invention preferably has a thickness of 0.5 μm to 10 μm. By having the thickness in this range, the insulating layer obtains high adhesion to conducting circuits.

The film used for the resin sheet of the present invention is not particularly limited. The examples include heat-resistant thermoplastic resin films comprising polyester resins such as polyethylene terephthalate and polybutylene terephthalate, fluorine resins and polyimide resins.

The metal foil used for the resin sheet of the present invention is not particularly limited. The examples include metal foils made of copper and/or a copper alloy, aluminum and/or an aluminum alloy, iron and/or an iron alloy, silver and/or a silver alloy, gold and/or a gold alloy, zinc and/or a zinc alloy, nickel and/or a nickel alloy, and tin and/or a tin alloy.

To produce the resin sheet of the present invention, the metal foil preferably has concaves and convexes on the surface, on which the insulating layer will be provided, with a surface roughness (Rz) of 2 μm or less. By laying the insulating layer comprising the resin composition of the present invention on the surface of the metal foil having a surface roughness (Rz) of 2 μm or less, the insulating layer has a small surface roughness and excellent adhesion (plating peel strength). The insulating layer preferably has a surface roughness (Rz) of 2 μm or less.

A lower limit of the surface roughness of the metal foil and insulating layer are not particularly limited. In general, they have a surface roughness (Rz) of 0.5 μm or more.

The surface roughness (Rz) of the metal is a ten point average roughness. The surface roughness is measured with reference to JIS B0601.

Next, the prepreg will be described.

The prepreg with the insulating layer of the present invention is obtained in such a manner that the base material is impregnated with the above-described resin composition of the present invention or a different resin composition, and then the insulating layer comprising the resin composition of the present invention is laid on both sides or either side of the base material, thereby obtaining a prepreg which is suitable for producing a printed wiring board having excellent adhesion to conducting circuits (plating peel strength).

In the case of providing the insulating layer comprising the resin composition of the present invention on a surface of the prepreg, the insulating layer preferably has a thickness of 0.5 μm to 10 μm, as with the insulating layer on the resin sheet.

A prepreg with an insulating layer shown in FIG. 4 is such that only insulating layer 2 is on one surface of prepreg 4, the layer comprising the resin composition of the present invention and the prepreg being a resin-impregnated prepreg. FIG. 5 shows such an example that only insulating layer 2 is on both surfaces of a stack of two prepregs 4 each, the layer comprising the resin composition of the present invention and the prepregs being a resin-impregnated prepreg each.

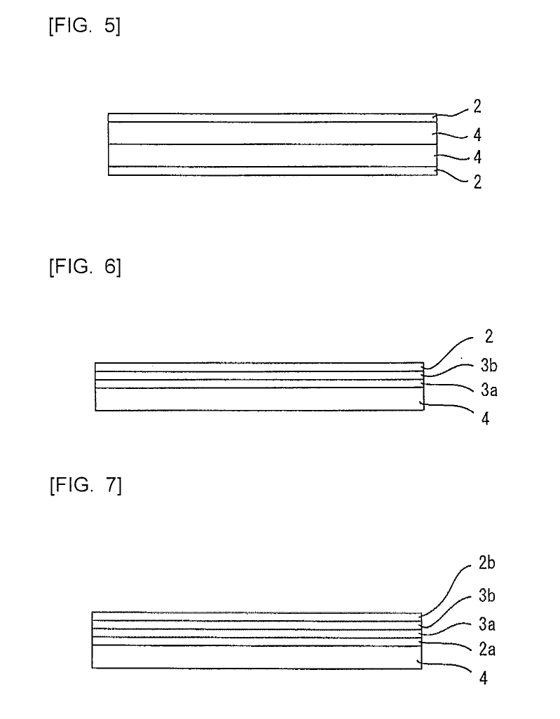

In the case where two or more insulating layers are on the prepreg, at least one of the insulating layers has only to be an insulating layer comprising the resin composition of the present invention. In this case, as shown in FIG. 6, the outermost insulating layer 2 with respect to prepreg 4 is preferably an insulating layer comprising the resin composition of the present invention. FIG. 7 shows such an example that two or more insulating layers are on prepreg 4, and the outermost (farthest) insulating layer 2b with respect to prepreg 4 and the innermost (closest) insulating layer 2a with respect to prepreg 4 are resin layers comprising the resin composition of the present invention, while other insulating layers are resin layers 3a and 3b each comprising a resin composition which is not the resin composition of the present invention.

The above-mentioned resin composition which is not the resin composition of the present invention is not particularly limited, and resin compositions that are generally used for the production of prepregs can be used. The examples include epoxy resin compositions and cyanate resin compositions.

The base material used for the production of the prepreg is not particularly limited, and the examples include the following: glass fiber base materials such as a glass woven fabric and a glass nonwoven fabric; synthetic fiber base materials that are made of woven or nonwoven fabrics mainly consisting of polyamide-based resin fibers such as a polyamide resin fiber, an aromatic polyamide resin fiber and a wholly aromatic polyamide resin fiber, polyester-based resin fibers such as a polyester resin fiber, an aromatic polyester resin fiber and a wholly aromatic polyester resin fiber, polyimide resin fibers and fluorine resin fibers; and organic fiber base materials including paper base materials having a main material selected from the group consisting of a craft paper, a cotton linter paper and a mixed paper of linter and craft pulp. Among them, glass fiber base materials are preferable. Thereby, there is an improvement in strength of the prepreg, and the prepreg obtains low water absorption properties and a small thermal expansion coefficient.

A glass type of the glass fiber base materials are not particularly limited, and the examples include E glass, C glass, A glass, S glass, D glass, NE glass, T glass and H glass. Among them, E glass and T glass are preferable. Thereby, the glass fiber base materials can obtain high elasticity and a small thermal expansion coefficient.

A method for producing the prepreg of the present invention is not particularly limited. The examples include a prepreg production method comprising the steps of: preparing a prepreg preliminarily in such a manner that a glass fiber material is impregnated with a varnish obtained by dissolving and dispersing a resin composition in a solvent and the solvent is volatilized by heat-drying; applying a resin varnish comprising the resin composition of the present invention to the prepreg; and volatilizing the solvent of the resin varnish by heat-drying. The examples also include a prepreg production method comprising the steps of: impregnating a glass fiber base material with a varnish obtained by dissolving and dispersing a resin composition in a solvent; immediately thereafter, applying a resin varnish comprising the resin composition of the present invention thereto; and then volatilizing the solvent of the resin varnish by heat-drying.

Next, the laminate will be described.

The laminate of the present invention is a cured product of a prepreg with an insulating layer, wherein one or more insulating layers each comprising a resin composition are on at least one surface of the prepreg, and at least one of the insulating layers is an insulating layer comprising the resin composition of the present invention.

The laminate of the present invention is obtained by laying a metal foil or a film on both surfaces of the prepreg with the insulating layer or a stack of the prepregs with the insulating layer, followed by heat-pressing.

The heating temperature is not particularly limited and is preferably 120 to 230° C., more preferably 150 to 220° C. The pressure to be applied is not particularly limited and is preferably 1 to 5 MPa, more preferably 1 to 3 MPa. A laminate is obtained thereby, which has excellent dielectric properties and excellent mechanical and/or electrical connection reliability at high temperature and high humidity.

Preferably, the surface of the prepreg with the insulating layer or the stack of the prepregs with the insulating layer, facing the metal foil or film is the insulating layer comprising the resin composition of the present invention, from the viewpoint of high adhesion. This is because the surface on which the metal foil or film will be laid becomes a surface that faces with a conducting circuit.

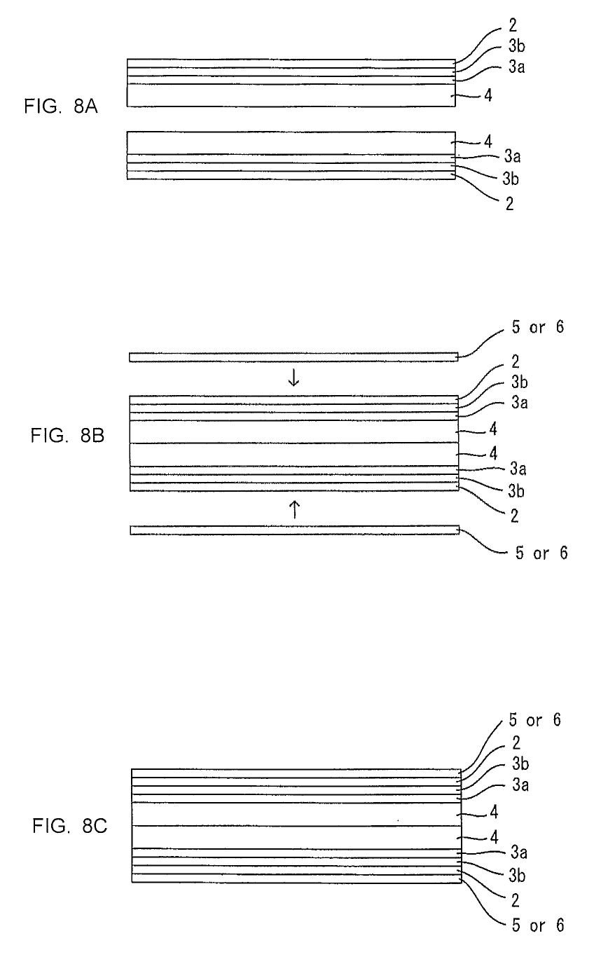

FIG. 8 shows an example of the laminate of the present invention. As shown in FIG. 8A, the prepreg with the insulating layer used in this example comprises three insulating layers 2, 3a and 3b which are provided on one surface of prepreg 4, and insulating layer 2 comprising the resin composition of the present invention is in the position which is farthest from the prepreg. After preparing two such prepregs, as shown in FIG. 8B, the prepregs are stacked so that their prepreg surfaces face each other, and the stack is sandwiched by metal foils 5 or films 6, followed by heat-pressing, thereby obtaining a laminate (FIG. 8C).

In this example, a metal foil-clad laminate is obtained if a metal foil such as a copper foil is laid on both surfaces of the prepreg or the stack of the prepregs as metal foil 5, while a laminate with a film is obtained if a film (film 6) is laid on both surfaces of the same.

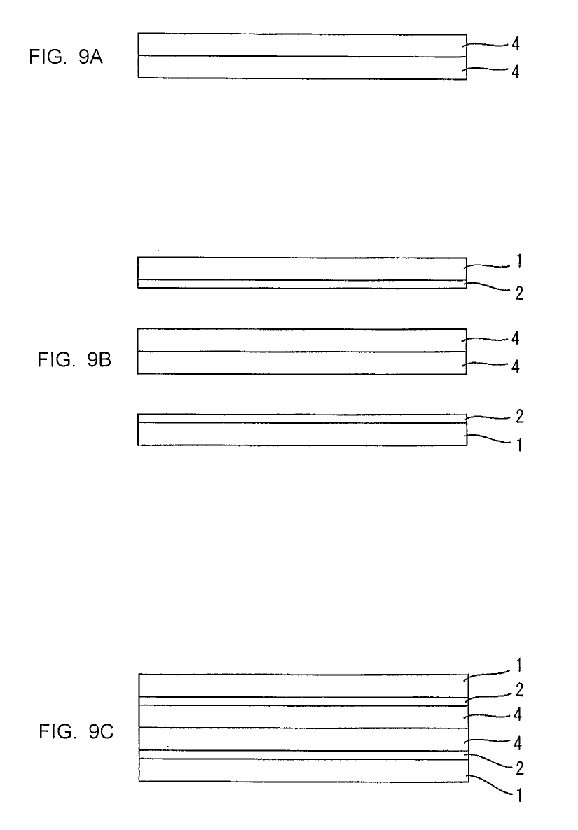

The laminate of the present invention can be obtained by using the resin sheet of the present invention. FIG. 9 shows an example of a laminate obtained by using the resin sheet. As shown in FIG. 9A, prepreg 4 or a stack of prepregs 4 is prepared. The prepreg(s) 4 can be impregnated with the resin composition of the present invention or a different resin composition. Next, as shown in FIG. 9B, the resin sheet of the present invention is prepared. In this example, two resin sheets of the present invention are prepared to be laid on both surfaces of the prepreg or stack. Each of the resin sheets used in this example comprises, on one surface of base material 1, only insulating layer 2 comprising the resin composition of the present invention, and comprises no other insulating layers. Then, as shown in FIG. 9C, the stack of two prepregs 4 is sandwiched by insulating layers 2 of the resin sheets so that the insulating layers face each other, followed by heat-pressing, thereby obtaining a laminate. In this example, a metal foil-clad laminate is obtained if a metal foil is used as base material 1 of the resin sheet, while a laminate with a film is obtained if a film is used as base material 1, a laminate with the film is obtained.

Even in this example, the outermost insulating layer of the laminate is insulating layer 2 comprising the resin composition of the present invention, so that the laminate has a surface having excellent adhesion, with which a conducting circuit will be in direct contact.

The laminate of the present invention can be also obtained by a method comprising the steps of laying the resin sheet of the present invention on the base material of a prepreg, such as a glass cloth, followed by heat-pressing. In this method, the insulating layer of the resin sheet is faced and laid on a surface of the base material of the prepreg being not impregnated with resin yet, followed by heat-pressing; thereby, part or all of the insulating layer on the resin sheet is melt and osmoses the base material, thereby forming a laminate.

Examples of the metal foil include metal foils made of copper, copper alloys, aluminum, aluminum alloys, silver, silver alloys, gold, gold alloys, zinc, zinc alloys, nickel, nickel alloys, tin, tin alloys, iron and iron alloys.

The film is not particularly limited. The examples include thermoplastic resin films having heat resistance, comprising polyester resins such as polyethylene terephthalate and polybutylene terephthalate, fluorine resins and polyimide resins.

Next, the multilayer printed wiring board of the present invention will be described.

A method for producing the multilayer printed circuit board of the present invention is not particularly limited. For example, the multilayer printed circuit board is obtained by laying the resin sheet or prepreg of the present invention and an inner layer circuit board, heat-pressing the stack under vacuum by means of a vacuum press laminator or the like, and then heat-curing the same by means of a hot air drying machine or the like.

A condition of the heat-pressing is not particularly limited. An example of the condition is a temperature of 60 to 160° C. and a pressure of 0.2 to 3 MPa. A condition of the heat-curing is not particularly limited. An example of the condition is a temperature of 140 to 240° C. and a time of 30 to 120 minutes.

The multilayer printed circuit board can be produced by a different method comprising the steps of laying the resin sheet or prepreg of the present invention on the inner layer circuit board and heat-pressing the same by means of a plate press machine or the like. A condition of the heat-pressing is not particularly limited. An example is a temperature of 140 to 240° C. and a pressure of 1 to 4 MPa.

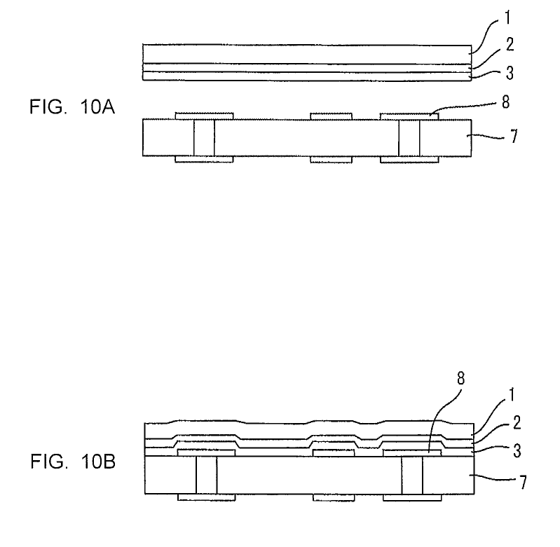

FIG. 10 shows an example of the method for producing the multilayer printed circuit board of the present invention. In this example, as shown in FIG. 10A, an inner layer circuit board and a resin sheet are prepared. The inner layer circuit board comprises inner layer circuit 8 and core substrate 7, and inner layer circuit 8 is on a surface of core substrate V. The resin sheet comprises insulating layer 2 comprising the resin composition of the present invention, base material 1 and insulating layer 3 comprising a resin composition which is not the resin composition of the present invention, and insulating layers 2 and 3 are on base material 1. In this resin sheet, insulating layer comprising the resin composition of the present invention is in the position which is closer to the base material. Next, as shown in FIG. 10B, the insulating layer of the resin sheet is faced and laid on the inner layer circuit on one surface of the core substrate, followed by heat-pressing, thereby covering the inner layer circuit with the insulating layer.

If the base material of the resin sheet is removed after the insulating layer covering the inner layer circuit, the insulating layer comprising the resin composition of the present invention is exposed; therefore, a conducting circuit can be formed thereon, thanks to excellent adhesion of the insulating layer. In addition, in the case where the base material of the resin sheet is a metal foil such as a copper foil, a pattern of a conducting circuit is formed by etching the metal foil, which has excellent adhesion to the insulating layer that is a base.

The inner layer circuit board is not particularly limited. For example, the inner layer circuit board can be produced as follows: through holes are formed in a laminate using a drill or the like; the through holes are filled by plating; a desired conducting circuit (inner layer circuit) is formed on both surfaces of the laminate by etching, etc.; and a roughening treatment such as a black oxide treatment is performed on the conducting circuit. As the laminate, it is preferable to use the laminate of the present invention.

Then, the metal foil or film is removed, and the surface of the insulating layer is roughened using an oxidant such as permanganate or bichromate. Thereafter, a new conducting wiring circuit is formed on the board obtained above by metal plating. The insulating layer comprising the resin composition of the present invention can form plurality of fine concavo-convex shapes with high uniformity in the roughening treatment process, and the surface of the insulating layer has high smoothness, so that a fine wiring circuit can be formed precisely.

Then, the insulating layer is cured by heating. The curing temperature is not particularly limited. For example, the insulating layer can be cured at a temperature in the range of 100° C. to 250° C., preferably in the range of 150° C. to 200° C.

Next, an opening is formed in the insulating layer by means of a CO₂ laser. An outer layer circuit is formed on the surface of the insulating layer by electrolytic copper plating to conduct electricity between the outer and inner layer circuits. An electrode part for connection, to which a semiconductor element is mounted, is provided to the outer layer circuit.

At last, a solder resist is formed on the outermost layer and the electrode part for connection is exposed by exposure and development, so that semiconductor elements can be mounted, followed by a nickel-gold plating process and cutting into a desired size, thereby obtaining the multilayer printed wiring board.

Next, the semiconductor device will be described.

The semiconductor device can be produced by mounting a semiconductor element on the multilayer printed wiring board. Methods for mounting and encapsulating a semiconductor element are not particularly limited. For example, the semiconductor device can be obtained as follows: a semiconductor element and a multilayer printed wiring board are prepared, and the position of the electrode part for connection on the multilayer printed wiring board and that of a solder bump of the semiconductor element are aligned by means of a flip chip bonder, etc.; the solder bump is heated to a temperature that is higher than the melting point by means of an IR reflow device, a heated plate or any other heating device, so that the solder bump is melted and connected to the multilayer printed wiring board; then, a liquid encapsulating resin is filled between the multilayer printed wiring board and the semiconductor element and cured, thereby obtaining the semiconductor device.

The present invention is not limited to the above embodiments, and modification and improvement within the range that the purpose of the present invention can be achieved are included in the present invention.

### EXAMPLES

Hereinafter, the present invention will be explained in detail with reference to examples. However, the present invention is not limited to the following examples and can be modified within the scope of the invention.

### Examples 1 to 9 and Comparative Examples 1 to 4

### Production of Multilayer Circuit Board

A resin varnish was produced, and a resin sheet and a prepreg with an insulating layer were produced using the resin varnish. Then, using the resin sheet and the prepreg with the insulating layer, an inner layer circuit of an inner layer circuit board was covered with the insulating layer to produce a multilayer circuit board.

### Example 1

### 1. Production of Varnish

### Production of First Resin Varnish (1A)

The following were agitated in a mixed solvent of dimethyl acetamide and methyl ethyl ketone for 30 minutes and dissolved: 31.5 parts by weight of a methoxynaphthalene aralkyl type epoxy resin (product name: EPICLON HP-5000; manufactured by: DIC Corporation) as the epoxy resin (A), 26.7 parts by weight of a phenol novolac type cyanate resin (product name: Primaset PT-30; manufactured by: Lonza Japan Ltd.) as the cyanate ester resin (B), 31.5 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 9.8 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing a first resin varnish (1A) having a solid content of 30%.

### Production of Second Resin Varnish (2A)

The following were agitated in methyl ethyl ketone for 30 minutes and dissolved: 17.0 parts by weight of a methoxynaphthalene aralkyl type epoxy resin (product name: EPICLON HP-5000; manufactured by: DIC Corporation), 11.0 parts by weight of a phenol novolac type cyanate resin (product name: Primaset PT-30; manufactured by: Lonza Japan Ltd.), 6.7 parts by weight of a phenoxy resin (product name: EPIKOTE YX-6954; manufactured by: Japan Epoxy Resins Co., Ltd.), and 0.3 part by weight of an imidazole (product name: CUREZOL 1B2PZ; manufactured by: Shikoku Chemicals Corporation). Furthermore, 0.3 part by weight of an epoxy silane coupling agent (product name: A187; manufactured by: Nippon Unicar Company Limited) and 64.7 parts by weight of a spherical fused silica (D) (product name: SO-25R; manufactured by: Admatechs Company Limited; average particle diameter: 0.5 μm) were added thereto and agitated for 10 minutes by means of a high speed agitator, thereby producing a second resin varnish (2A) having a solid content of 50%.

### 2. Production of Resin Sheet

The first resin varnish obtained above was applied onto one surface of a PET (polyethylene terephthalate) film having a thickness of 25 μm by means of a comma coater so that the resulting insulating layer has a thickness of 3 μm when dried, and dried by means of a drying machine at 160° C. for 3 minutes.

Next, the second resin varnish was further applied onto the upper surface of the insulating layer comprising the first resin varnish by means of a comma coater so that the resulting insulating layer and the above-obtained insulating layer have a total thickness of 30 μm when dried, and dried by means of a drying machine at 160° C. for 3 minutes, thereby obtaining a resin sheet having an insulating layer with a double-layered structure.

### 3. Production of Multilayer Printed Wiring Board

To measure surface roughness (Rz) and plating peel strength that will be described hereinafter, a multilayer printed wiring board was produced first.

The multilayer printed wiring board was produced as follows: the inner layer circuit board having a predetermined inner layer circuit pattern formed on both surfaces thereof was sandwiched by the resin sheets obtained above so that the insulating layer-surface of the resin sheets face inside. The resultant was heat-pressed under vacuum at a temperature of 100° C. and a pressure of 1 MPa by means of a vacuum press laminator, followed by heat-curing at 170° C. for 60 minutes by means of a hot air drying machine, thereby producing a multilayer printed wiring board.

As the inner layer circuit board, the following copper-clad laminate was used.

Insulating layer: Halogen free FR-4 material (thickness: 0.4 mm)

Conducting layer: Copper foil (thickness: 18 μm; L/S: 120/180 μm; clearance hole: 1 mmφ and 3 mmφ; slit: 2 mm)

### 4. Production of Semiconductor Device

The base material was removed from the multilayer printed wiring board obtained above. The board was immersed in a swelling agent (product name: Swelling Dip Securiganth P; manufactured by: Atotech Japan K.K.) at 80° C. for 10 minutes. In addition, the board was immersed in a potassium permanganate aqueous solution (product name: Concentrate Compact CP; manufactured by: Atotech Japan K.K.) at 80° C. for 20 minutes, followed by neutralization and a roughening treatment.

The board was subjected to the processes of degreasing, providing a catalyst and activation. Thereafter, an electroless copper plating film having a thickness of about 1 μm and an electrolytic copper plating having a thickness of 30 μm were formed on the board, and an annealing treatment was performed thereon at 200° C. for 60 minutes by means of a hot air drying machine.

Next, a solder resist (product name: PSR-4000 AUS703; manufactured by: Taiyo Ink Mfg. Co., Ltd.) was printed on the board and exposed to light through a predetermined mask so that a semiconductor element mounting pad and so on are exposed, followed by development and curing, thereby forming a solder resist layer having a thickness of 12 μm on the circuit.

Finally, a plated layer was formed on the circuit layer exposed from the solder resist layer, the plated layer comprising an electroless nickel plating layer (3 μm) and an electroless gold plating layer (0.1 μm) on the electroless nickel plating layer. The thus-obtained board was cut into a size of 50 mm×50 mm, thereby obtaining a multilayer printed wiring board for semiconductor devices.

The semiconductor device was obtained as follows: a semiconductor element having a solder bump (TEG chip, size: 15 mm×15 mm; thickness: 0.8 mm) was mounted on the multilayer printed wiring board for semiconductor devices by thermal compression using a flip chip bonder; the solder bump was melted with an IR reflow furnace to connect the board; and a liquid encapsulating resin (product name: CRP-4152S; manufactured by: Sumitomo Bakelite Co., Ltd.) was filled and cured to obtain the semiconductor device. The liquid encapsulating resin was cured in the condition of a temperature of 150° C. and a time of 120 minutes.

The solder bump used for the semiconductor element is one comprising a Sn/Pb eutectic.

### Example 2

A resin sheet, a multilayer printed wiring board and a semiconductor device were obtained similarly as in Example 1 except that a first resin varnish (1B) was produced as follows instead of the first resin varnish (1A).

### Production of First Resin Varnish (1B)

The following were agitated in a mixed solvent of dimethyl acetamide and methyl ethyl ketone for 30 minutes and dissolved: 32.0 parts by weight of a methoxynaphthalene aralkyl type epoxy resin (product name: EPICLON HP-5000; manufactured by: DIC Corporation) as the epoxy resin (A), 16.0 parts by weight of a phenol novolac type cyanate resin (product name: Primaset PT-30; manufactured by: Lonza Japan Ltd.) as the cyanate ester resin (B), 32.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 19.5 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1B) having a solid content of 30%.

### Example 3

A resin sheet, a multilayer printed wiring board and a semiconductor device were obtained similarly as in Example 1 except that a first resin varnish (1C) was produced as follows instead of the first resin varnish (1A).

### Production of First Resin Varnish (1C)

The following were agitated in a mixed solvent of dimethyl acetamide and methyl ethyl ketone for 30 minutes and dissolved: 64.4 parts by weight of a methoxynaphthalene aralkyl type epoxy resin (product name: EPICLON HP-5000; manufactured by: DIC Corporation) as the epoxy resin (A), 9.7 parts by weight of a phenol novolac type cyanate resin (product name: Primaset PT-30; manufactured by: Lonza Japan Ltd.) as the cyanate ester resin (B), 20.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.1 part by weight of an epoxy silane coupling agent (product name: A187; manufactured by: Nippon Unicar Company Limited) as a coupling agent and 5.5 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1C) having a solid content of 30%.

### Example 4

A resin sheet, a multilayer printed wiring board and a semiconductor device were obtained similarly as in Example 1 except that a first resin varnish (1D) was produced as follows instead of the first resin varnish (1A).

### Production of First Resin Varnish (1D)

The following were agitated in a mixed solvent of dimethyl acetamide and methyl ethyl ketone for 30 minutes and dissolved: 5.0 parts by weight of a methoxynaphthalene aralkyl type epoxy resin (product name: EPICLON HP-5000; manufactured by: DIC Corporation) and 25.0 parts by weight of a bisphenol A type epoxy resin (product name: EPICLON 7050; manufactured by: DIC Corporation) as the epoxy resin (A), 26.7 parts by weight of a phenol novolac type cyanate resin (product name: Primaset PT-30; manufactured by: Lonza Japan Ltd.) as the cyanate ester resin (B), 33.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 9.8 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1D) having a solid content of 30%.

### Example 5

A resin sheet, a multilayer printed wiring board and a semiconductor device were obtained similarly as in Example 1 except that a first resin varnish (1E) was produced as follows instead of the first resin varnish (1A).

### Production of First Resin Varnish (1E)

The following were agitated in a mixed solvent of dimethyl acetamide and methyl ethyl ketone for 30 minutes and dissolved: 10.0 parts by weight of a methoxynaphthalene aralkyl type epoxy resin (product name: EPICLON HP-5000; manufactured by: DIC Corporation) as the epoxy resin (A), 9.1 parts by weight of a phenol novolac type cyanate resin (product name: Primaset PT-30; manufactured by: Lonza Japan Ltd.) as the cyanate ester resin (B), 75.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.1 part by weight of an epoxy silane coupling agent (product name: A187; manufactured by: Nippon Unicar Company Limited) as a coupling agent and 5.5 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1E) having a solid content of 30%.

### Example 6

A resin sheet, a multilayer printed wiring board and a semiconductor device were obtained similarly as in Example 1 except that a first resin varnish (1F) was produced as follows instead of the first resin varnish (1A).

### Production of First Resin Varnish (1F)

The following were agitated in a mixed solvent of dimethyl acetamide and methyl ethyl ketone for 30 minutes and dissolved: 32.0 parts by weight of a methoxynaphthalene aralkyl type epoxy resin (product name: EPICLON HP-5000; manufactured by: DIC Corporation) as the epoxy resin (A), 35.0 parts by weight of a phenol novolac type cyanate resin (product name: Primaset PT-30; manufactured by: Lonza Japan Ltd.) as the cyanate ester resin (B), 13.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 19.5 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1F) having a solid content of 30%.

### Example 7

A resin sheet, a multilayer printed wiring board and a semiconductor device were obtained similarly as in Example 1 except that a first resin varnish (1G) was produced as follows instead of the first resin varnish (1A).

### Production of First Resin Varnish (1G)

The following were agitated in a mixed solvent of dimethyl acetamide and methyl ethyl ketone for 30 minutes and dissolved: 32.0 parts by weight of a methoxynaphthalene aralkyl type epoxy resin (product name: EPICLON HP-5000; manufactured by: DIC Corporation) as the epoxy resin (A), 16.0 parts by weight of a bisphenol A type cyanate resin (product name: Primaset BA-230; manufactured by: Lonza Japan, Ltd.) as the cyanate ester resin (B), 32.0 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an manufactured by: Nippon Unicar Company Limited) as a coupling agent and 19.5 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed agitator, thereby producing the resin varnish (1G) having a solid content of 30%.

### Example 8

A resin sheet, a multilayer printed wiring board and a semiconductor device were obtained similarly as in Example 1 except that a first resin varnish (1H) was produced as follows instead of the first resin varnish (1A).

### Production of First Resin Varnish (1H)

The following were agitated in a mixed solvent of dimethyl acetamide and methyl ethyl ketone for 30 minutes and dissolved: 31.5 parts by weight of a methoxynaphthalene aralkyl type epoxy resin (product name: EPICLON HP-5000; manufactured by: DIC Corporation) as the epoxy resin (A), 26.7 parts by weight of a phenol novolac type cyanate resin (product name: Primaset PT-30; manufactured by: Lonza Japan Ltd.) as the cyanate ester resin (B), 31.5 parts by weight of a hydroxyl group-containing polyamide resin (product name: KAYAFLEX BPAM01; manufactured by: Nippon Kayaku Co., Ltd.) as the aromatic polyamide resin (C) containing at least one hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 9.8 parts by weight of a spherical fused silica (product name: SO-32R; manufactured by: Admatechs Company Limited; average particle diameter: 1.5 μm) as the inorganic filler (D) were added thereto and agitated for 10 minutes by means of a high speed agitator, thereby producing the resin varnish (1H) having a solid content of 30%.

### Example 9

### Production of Prepreg

A glass woven fabric (product name: E10T cloth; manufactured by: UNITIKA. LTD.; 90 μm) was impregnated with the second resin varnish (2A), and the first resin varnish (1A) was applied onto one surface of the second resin varnish (2A) which was impregnated in the glass woven fabric. Then, the glass woven fabric was dried in a heating furnace at 150° C. for 2 minutes, thereby producing a prepreg having a thickness of 100 μm (the thickness of the prepreg impregnated with the second resin varnish: 95 μm; the thickness of the same after the first resin varnish was applied thereto: 100 μm).

A multilayer printed wiring board and a semiconductor device were produced similarly as in Example 1 except that the prepreg was used instead of the resin sheet.

### Comparative Example 1

A multilayer printed wiring board and a semiconductor device were obtained similarly as in Example 1 except that a first resin varnish (1I) was produced as follows instead of the first resin varnish (1A), and the first resin varnish (1I) was applied onto one surface of a PET (polyethylene terephthalate) film having a thickness of 25 μm by means of a comma coater so that the resulting insulating layer will have a thickness of 30 μm when dried, and dried by means of a drying machine at 160° C. for 3 minutes, thereby obtaining a resin sheet.

### Production of First Resin Varnish (1I)

The following were agitated in methyl ethyl ketone for 30 minutes and dissolved: 24.0 parts by weight of a methoxynaphthalene aralkyl type epoxy resin (product name: EPICLON HP-5000; manufactured by: DIC Corporation), 23.7 parts by weight of a phenol novolac type cyanate resin (product name: Primaset PT-30; manufactured by: Lonza Japan Ltd.), 12.0 parts by weight of a phenoxy resin (product name: EPIKOTE YX-6954; manufactured by: Japan Epoxy Resins Co., Ltd.) and 0.3 part by weight of an imidazole (product name: CUREZOL 1B2PZ; manufactured by: Shikoku Chemicals Corporation). Furthermore, 0.2 part by weight of an epoxy silane coupling agent (product name: A187; manufactured by: Nippon Unicar Company Limited) and 39.8 parts by weight of a spherical fused silica (D) (product name: SO-25R; manufactured by: Admatechs Company Limited; average particle diameter: 0.5 μm) were added thereto and agitated for 10 minutes by means of a high speed agitator, thereby obtaining the resin varnish (1I) having a solid content of 50%.

### Comparative Example 2

A resin sheet, a multilayer printed wiring board and a semiconductor device were obtained similarly as in Comparative example 1 except that a first resin varnish (1J) was produced as follows instead of the first resin varnish (1I).

### Production of First Resin Varnish (1J)

The following were agitated in methyl ethyl ketone for 30 minutes and dissolved: 18.0 parts by weight of a methoxynaphthalene aralkyl type epoxy resin (product name: EPICLON HP-5000; manufactured by: DIC Corporation), 17.7 parts by weight of a phenol novolac type cyanate resin (product name: Primaset PT-30; manufactured by: Lonza Japan, Ltd.), 9.0 parts by weight of a phenoxy resin (product name: EPIKOTE YX-6954; manufactured by: Japan Epoxy Resins Co., Ltd.) and 0.3 part by weight of an imidazole (product name: CUREZOL 1B2PZ; manufactured by: Shikoku Chemicals Corporation). Furthermore, 0.3 part by weight of an epoxy silane coupling agent (product name: A187; manufactured by: Nippon Unicar Company Limited) and 54.7 parts by weight of a spherical fused silica (D) (product name: SO-25R; manufactured by: Admatechs Company Limited; average particle diameter: 0.5 μm) were added thereto and agitated for 10 minutes by means of a high speed agitator, thereby obtaining the resin varnish (1J) having a solid content of 50%.

### Comparative Example 3

A resin sheet, a multilayer printed wiring board and a semiconductor device were obtained similarly as in Example 1 except that a first resin varnish (1K) was produced as follows instead of the first resin varnish (1A).

### Production of First Resin Varnish (1K)

The following were agitated in NMP for 30 minutes and dissolved: 31.5 parts by weight of a methoxynaphthalene aralkyl type epoxy resin (product name: EPICLON HP-5000; manufactured by: DIC Corporation) as the epoxy resin (A), 26.7 parts by weight of a phenol novolac type cyanate resin (product name: Primaset PT-30; manufactured by: Lonza Japan Ltd.) as the cyanate ester resin (B), 31.5 parts by weight of a polyamide-imide resin (product name: VYLOMAX HR11NN; manufactured by: Toyobo Co., Ltd.) as a polyamide resin containing no hydroxyl group, and 0.3 part by weight of an imidazole (product name: CUREZOL 1B2PZ; manufactured by: Shikoku Chemicals Corporation) as a curing catalyst. Furthermore, 0.2 part by weight of an epoxy silane coupling agent (product name: A187; manufactured by: Nippon Unicar Company Limited) as a coupling agent and 9.8 parts by weight of a spherical fused silica (product name: SO-25R; manufactured by: Admatechs Company Limited; average particle diameter: 0.5 μm) as the inorganic filler (D) were added thereto and agitated for 10 minutes by means of a high speed having a solid content of 30%.

Table 1 lists the components of each resin varnish used in Examples and Comparative examples.

TABLE 1

| | | E- | Resin | Resin | Resin | Resin | Resin | Resin | Resin | Resin | Resin | Resin | Resin | Resin |
|---|---|---|---|---|---|---|---|---|---|---|---|---|---|---|
| | | quiv- | varnish | varnish | varnish | varnish | varnish | varnish | varnish | varnish | varnish | varnish | varnish | varnish |
| | | alent | 1A | 1B | 1C | 1D | 1E | 1F | 1G | 1H | 1I | 1J | 1K | 2A |
| (A) | Methoxynaph- | 250 | 31.5 | 32.0 | 64.4 | 5.0 | 10.0 | 32.0 | 32.0 | 31.5 | 24.0 | 18.0 | 31.5 | 17.0 |
| Epoxy | thalene aralkyl | | | | | | | | | | | | | |
| resin | type epoxy | | | | | | | | | | | | | |
| | resin (EPICLON | | | | | | | | | | | | | |
| | HP-5000) | | | | | | | | | | | | | |
| | Bisphenol A | 2,000 | | | | 25.0 | | | | | | | | |
| | type epoxy resin | | | | | | | | | | | | | |
| | (EPICLON | | | | | | | | | | | | | |
| | 7050) | | | | | | | | | | | | | |
| (B) | Phenol novolac | | 26.7 | 16.0 | 9.7 | 26.7 | 9.1 | 35.0 | | 26.7 | 23.7 | 17.7 | 26.7 | 11.0 |
| Cya- | type cyanate | | | | | | | | | | | | | |
| nate | resin (Primaset | | | | | | | | | | | | | |
| resin | PT-30) | | | | | | | | | | | | | |
| | Bisphenol A | | | | | | | | 16.0 | | | | | |
| | type cyanate | | | | | | | | | | | | | |
| | resin (Primaset | | | | | | | | | | | | | |
| | BA-230) | | | | | | | | | | | | | |
| (C) | Aromatic | 4,000 | 31.5 | 32.0 | 20.0 | 33.0 | 75.0 | 13.0 | 32.0 | 31.5 | | | | |
| Poly- | polyamide | | | | | | | | | | | | | |
| amide | resin containing | | | | | | | | | | | | | |
| resin | at least one | | | | | | | | | | | | | |
| | hydroxyl group | | | | | | | | | | | | | |
| | (KAYAFLEX | | | | | | | | | | | | | |
| | BPAM01) | | | | | | | | | | | | | |
| | Polyamide- | | | | | | | | | | | | 31.5 | |
| | imide resin | | | | | | | | | | | | | |
| | (VYLOMAX | | | | | | | | | | | | | |
| | HR11NN) | | | | | | | | | | | | | |
| (D) | Fused silica | | 9.8 | 19.5 | 5.5 | 9.8 | 5.5 | 19.5 | 19.5 | | 39.8 | 54.7 | 9.8 | 64.7 |
| Inor- | (SO25R) | | | | | | | | | | | | | |
| ganic | Fused silica | | | | | | | | | 9.8 | | | | |
| filler | (SO32R) | | | | | | | | | | | | | |
| Phen- | Phenoxy resin | | | | | | | | | | 12.0 | 9.0 | | 6.7 |
| oxy | (EPIKOTE | | | | | | | | | | | | | |
| resin | YX6954) | | | | | | | | | | | | | |
| Curing | Imidazole | | 0.3 | 0.3 | 0.3 | 0.3 | 0.3 | 0.3 | 0.3 | 0.3 | 0.3 | 0.3 | 0.3 | 0.3 |
| catalyst | (1B2PZ) | | | | | | | | | | | | | |
| Cou- | Epoxy silane | | 0.2 | 0.2 | 0.1 | 0.2 | 0.1 | 0.2 | 0.2 | 0.2 | 0.2 | 0.3 | 0.2 | 0.3 |
| pling | coupling | | | | | | | | | | | | | |
| agent | agent (A187) | | | | | | | | | | | | | |

| | | | | | | | | | | | | |
|---|---|---|---|---|---|---|---|---|---|---|---|---|
| Total | 100.0 | 100.0 | 100.0 | 100.0 | 100.0 | 100.0 | 100.0 | 100.0 | 100.0 | 100.0 | 100.0 | 100.0 |
| Equivalent ratio | 0.06 | 0.06 | 0.02 | 0.25 | 0.47 | 0.03 | 0.06 | 0.06 | | | | |
| of (A) and (C) | | | | | | | | | | | | |

The resin sheet, the prepreg, the multilayer printed wiring board and the semiconductor device obtained in each of Examples and Comparative examples were evaluated for the following properties. The obtained results are shown in Tables 2 and 3.

TABLE 2

| Evaluation | | Example | Example | Example | Example | Example | Example | Example | Example | Example |
|---|---|---|---|---|---|---|---|---|---|---|
| item | Unit | 1 | 2 | 3 | 4 | 5 | 6 | 7 | 8 | 9 |
| (1) Thermal | ppm | ∘ | ∘ | ∘ | ∘ | Δ | ∘ | ∘ | ∘ | ∘ |
| expansion | | | | | | | | | | |
| coefficient | | | | | | | | | | |
| (2) Glass | deg C. | 175 | 175 | 165 | 180 | 175 | 180 | 170 | 175 | 175 |
| transition | | | | | | | | | | |
| temperature | | | | | | | | | | |
| (3) Surface | μm | 0.20 | 0.26 | 0.17 | 0.21 | 0.27 | 0.27 | 0.21 | 0.30 | 0.25 |
| roughness | | | | | | | | | | |
| (4) Plating | kgf/cm | ∘ | ∘ | ∘ | ∘ | ∘ | ∘ | ∘ | ∘ | ∘ |
| peel strength | | | | | | | | | | |
| (5) Thermal | | ∘ | ∘ | ∘ | ∘ | ∘ | ∘ | ∘ | ∘ | ∘ |
| shock test | | | | | | | | | | |

TABLE 3

| | | Compar- | Compar- | Compar- |
|---|---|---|---|---|
| | | ative | ative | ative |
| Evaluation item | Unit | example 1 | example 2 | example 3 |
| (1) Thermal expansion | ppm | Δ | Δ | ∘ |
| coefficient | | | | |
| (2) Glass transition | degC | 175 | 175 | 175 |
| temperature | | | | |
| (3) Surface roughness | μm | 0.24 | 0.23 | 0.24 |
| (4) Plating peel strength | kgf/cm | x | x | x |
| (5) Thermal shock test | | ∘ | ∘ | ∘ |

Evaluation of the items in Tables 2 and 3 were conducted by the following methods.

### (1) Thermal Expansion Coefficient

Two resin sheets were stacked so that the insulating layers of the sheets face each other. After the resultant was heat-pressed at a pressure of 2 MPa and a temperature of 200° C. for 2 hours by means of a vacuum press machine, the base material was removed by peeling, thereby obtaining a cured resin product. Then, a test piece of 4 mm×20 mm was taken from the thus-obtained cured resin product and measured by means of a TMA (thermomechanical analyzer manufactured by TA Instruments), increasing and decreasing the temperature from 0° C. to 260° C. at a rate of 10° C./minute. The symbols refer to the following:
∘: Less than 30 ppm
Δ: 30 ppm or more and less than 40 ppm
×: 40 ppm or more

### (2) Glass Transition Temperature (Tg)

Based on the results of the thermomechanical analysis for measuring the above (1) Thermal expansion coefficient, the glass transition temperature was determined from an infection point shown in the graph.

### (3) Surface Roughness (Rz)

After the multilayer printed wiring boards obtained above were roughened, they were measured for surface roughness (Rz) by means of a laser microscope (product name: VK-8510; manufactured by: KEYENCE Corporation; PITCH: 0.02 μm; RUN mode: Color ultra-depth). Rz is a ten point average roughness.

### (4) Plating Peel Strength

The copper plating was removed from each multilayer printed wiring board by peeling to measure the plating peel strength with reference to JIS C-6481. The symbols refer to the following:
∘: 0.7 kN/m or more
×: Less than 0.7 kN/m

### (5) Thermal Shock Test

The semiconductor devices obtained above underwent 1,000 cycles of −55° C. for 30 minutes and 125° C. for 30 minutes in Fluorinert. Then, they were checked for the presence of crack in the board or semiconductor element thereof. The symbols refer to the following:
∘: No crack was observed
×: Crack was observed

### Example 10 and Comparative Example 4

### Production of Copper-Clad Laminate

A resin varnish was produced, and the resin varnish was applied onto a copper base material to produce a resin sheet. Furthermore, the resin sheet was laminated on both surfaces of a prepreg, thereby producing a copper-clad laminate.

### Example 10

### 1. Production of Varnish

The following were agitated in a mixed solvent of dimethyl acetamide and methyl ethyl ketone for 30 minutes and dissolved: 31.6 parts by weight of a methoxynaphthalene aralkyl type epoxy resin (product name: EPICLON HP-5000; manufactured by: DIC Corporation) as the epoxy resin (A), 15.8 parts by weight of a phenol novolac type cyanate resin (product name: Primaset PT-30; manufactured by: Lonza Japan Ltd.) as the cyanate ester resin (B), 31.6 parts by weight of a hydroxyl group-containing polyamide resin (product name: KAYAFLEX BPAM155; manufactured by: Nippon Kayaku Co., Ltd.) as an aromatic polyamide resin (C) containing at least one hydroxyl group, and 0.2 part by weight of an imidazole (product name: CUREZOL 1B2PZ; manufactured by: Shikoku Chemicals Corporation) as a curing catalyst. Furthermore, 0.1 part by weight of an epoxy silane coupling agent (product name: A187; manufactured by: Nippon Unicar Company Limited) as a coupling agent, 19.9 parts by weight of a spherical fused silica (product name: SC-1030; manufacture by: Admatechs Company Limited; average particle diameter: 0.3 μm) as the inorganic filler (D) and a leveling agent (product name: BYK-361N; manufactured by: BYK Japan KK) were added thereto and agitated for 10 minutes by means of a high speed agitator, thereby producing a resin varnish having a solid content of 30%.

### 2. Production of Resin Sheet

The resin varnish obtained above was applied onto one surface of an unroughened copper foil (product name: YSNAP-3PF; manufactured by: Nippon Denkai, Ltd.) having a thickness of 3 μm by means of a comma coater so that the resulting insulating layer has a thickness of 3 μm when dried, and dried by means of a drying machine at 160° C. for 3 minutes, thereby obtaining a resin sheet comprising the copper foil base material and, thereon, only the insulating layer comprising the resin composition of the present invention.

### 3. Production of Copper-Clad Laminate

Two prepregs for core substrates were stacked, each having a thickness of 0.1 mm and comprising a glass woven fabric impregnated with a novolac type cyanate resin (product name: EI-6785GS; manufactured by: Sumitomo Bakelite Co., Ltd.). The stack was sandwiched by the resin sheets so that the insulating layer of the resin sheet faces the prepreg. The stack was heat-pressed under vacuum at a temperature of 100° C. and a pressure of 1 MPa by means of a vacuum press laminator, followed by heat-curing at 170° C. for 60 minutes by means of a hot air drying machine, thereby producing a copper-clad laminate.

### Comparative Example 4

A copper-clad laminate was obtained similarly as in Example 10 except that the stack of prepregs was sandwiched by copper foil base materials as they were instead of the resin sheet used in Example 10.

The copper-clad laminates obtained in Example 10 and Comparative example 4 were evaluated for the following. The results of Example 10 and Comparative example 4 are shown in Tables 4 and 5. Table 4 lists the components of the resin varnish used in Example 10. Table 5 shows the layer constitution and evaluation result of each copper-clad laminate obtained in Example 10 and Comparative example 4.

### (1) Copper Foil Peel Strength

Peel strength (unit: kN/m) of the copper foil from the prepreg was measured with reference to JIS C-6481 similarly as the plating peel strength of the multilayer printed wiring board.

### (2) Solder Heat Resistance After Moisture Absorption

Solder heat resistance after moisture absorption of each copper-clad laminate was evaluated as follows with reference to JIC C-6481. A 50 mm square sample was cut out from the copper-clad laminate, and three-quarters of the copper-clad laminate was etched. Following D-2/100 treatment, the sample was immersed in solder at 260° C. for 30 seconds to see if there is a blister. The symbols refer to the following:
∘: No blister was observed
×: Blister was observed

TABLE 4
Resin composition for copper-clad laminate

| | | Equivalent | Ratio (%) |
|---|---|---|---|
| (A) Epoxy | Methoxynaphthalene aralkyl type | 250 | 31.6 |
| resin | epoxy resin (EPICLON HP-5000) | | |
| (B) Cyanate | Phenol novolac type cyanate resin | | 15.8 |
| resin | (Primaset PT-30) | | |
| (C) Polyamide | Aromatic polyamide resin | 4,000 | 31.6 |
| resin | containing at least one hydroxyl | | |
| | group (KAYAFLEX BPAM155) | | |
| (D) Inorganic | Spherical fused silica | | 19.9 |
| filler | (SC-1030; average particle | | |
| | diameter: 0.3 μm) | | |
| Curing catalyst | Imidazole (1B2PZ) | | 0.2 |
| Coupling agent | Epoxy silane coupling agent | | 0.1 |
| Leveling agent | BYK-361N | | 0.8 |

| | |
|---|---|
| Total | 100 |
| Equivalent ratio of (A) and (C) | 0.06 |

TABLE 5

| | | | Comparative |
|---|---|---|---|
| | | Example 10 | example 4 |
| Layer | Copper foil | Unroughened copper | Unroughened copper |
| constitution | | foil (thickness: 3 μm; | foil (thickness: 3 μm; |
| | | YSNAP-3PF) | YSNAP-3PF) |
| | Insulating layer | ∘ | x |
| | Prepreg for core | Thickness: 100 μm | Thickness: 100 μm |
| | | (El-6785GS) × 2 | (El-6785GS) × 2 |
| Evaluation | Copper foil peel | 0.99 | 0.61 |
| | strength (kN/m) | | |
| | Solder heat | No blister observed | Blister observed |
| | resistance after | | |
| | moisture | | |
| | absorption | | |

In Examples 1 to 9, the resin composition of the present invention was used. The resin composition obtained excellent results in all the evaluation items including a low thermal expansion coefficient and high glass transition temperature; moreover, the insulating layer comprising the resin composition of the present invention had fine roughened shapes on the surface thereof and showed sufficient plating peel strength. On the other hand, Comparative examples 1 to 3 are examples in which the aromatic polyamide resin (C) containing at least one hydroxyl group was not used, and they resulted in poor plating peel strength. Comparative example 4 is an example in which a polyamide-imide resin containing no hydroxyl group was used.

Example 10 is a copper-clad laminate in which the copper foil was attached to both surfaces of the stack of prepregs via the insulating layer comprising the resin composition of the present invention. Example 10 showed high copper foil peel strength, and no blister was observed in the solder heat resistance after moisture absorption test. Comparative example 4 is a copper-clad laminate in which the copper foil was directly attached to both surfaces of the stack of prepregs. Comparative example 4 showed lower copper foil peel strength than Example 10, and blister was observed in the solder heat resistance after moisture absorption test.

### INDUSTRIAL APPLICABILITY

The resin composition of the present invention has a low thermal expansion coefficient and a high glass transition temperature; moreover, the insulating layer comprising the resin composition of the present invention has fine roughened shapes on the surface thereof and shows sufficient plating peel strength or metal foil peel strength. Therefore, the resin composition of the present invention can be efficiently used for multilayer printed wiring boards requiring the formation of finer circuits, having a conducting circuit width of, for example, less than 10 μm.

1. A resin composition comprising (A) an epoxy resin, (B) a cyanate ester resin, (C) an aromatic polyamide resin containing at least one hydroxyl group and (D) an inorganic filler, as essential components.

2. The resin composition according to claim 1, wherein an equivalent ratio of an active hydrogen equivalent of the aromatic polyamide resin (C) containing at least one hydroxyl group is 0.02 or more and 0.2 or less with respect to an epoxy equivalent of the epoxy resin (A).

3. The resin composition according to claim 1, wherein the aromatic polyamide resin (C) containing at least one hydroxyl group contains a segment comprising a repeating unit having a diene skeleton and four or more carbons.

4. The resin composition according to claim 1, wherein a content of the aromatic polyamide resin (C) containing at least one hydroxyl group is 20 to 70% by weight of a total content of the resin composition.

5. The resin composition according to claim 1, wherein the cyanate ester resin (B) is a novolac type cyanate ester resin.

6. The resin composition according to claim 1, wherein the inorganic filler (D) is one or more kinds selected from the group consisting of magnesium hydroxide, aluminum hydroxide, silica, talc, calcined talc and alumina.

7. The resin composition according to claim 1, wherein the inorganic filler (D) has an average particle diameter of 5.0 μm or less.

8. A resin sheet comprising a base material and an insulating layer on the base material, wherein the insulating layer comprises the resin composition defined by claim 1.

9. The resin sheet according to claim 8, wherein only the insulating layer comprising the resin composition is on the base material.

10. The resin sheet according to claim 8, wherein two or more insulating layers each comprising a resin composition are on the base material, and at least one of the insulating layers is an insulating layer comprising the resin composition having components (A)-(D).

11. The resin sheet according to claim 8, wherein a layer closest to the base material is an insulating layer comprising the resin composition having components (A)-(D).

12. The resin sheet according to claim 8, wherein the insulating layer comprising the resin composition defined by claim 1 has a thickness of 0.5 μm to 10 μm.

13. The resin sheet according to claim 8, wherein the insulating layer comprising the resin composition has an average surface roughness of 2.0 μm or less.

14. A prepreg with an insulating layer, wherein the insulating layer comprising the resin composition defined by claim 1 is on at least one surface of the prepreg.

15. The prepreg with the insulating layer according to claim 14, wherein only the insulating layer comprising the resin composition is on at least one surface of the prepreg.

16. The prepreg with the insulating layer according to claim 14, wherein one or more insulating layers each comprising a resin composition are on at least one surface of the prepreg, and at least one of the insulating layers is an insulating layer comprising the resin composition having components (A)-(D).

17. The prepreg with the insulating layer according to claim 14, wherein an outermost insulating layer with respect to the prepreg is an insulating layer comprising the resin composition.

18. The prepreg with the insulating layer according to claim 14, wherein the insulating layer comprising the resin composition has a thickness of 0.5 μm to 10 μm.

19. A laminate comprising a cured product of a prepreg with an insulating layer, wherein one or more insulating layers each comprising a resin composition are on at least one surface of the prepreg, and at least one of the insulating layers is an insulating layer comprising the resin composition defined by claim 1.

20. The laminate according to claim 19, wherein an outermost layer of the insulating layers is an insulating layer comprising the resin composition having components (A)-(D).

21. The laminate according to claim 19, obtained by laying a resin sheet on at least one surface of the prepreg so that the insulating layer of the resin sheet faces the prepreg, and heat-pressing them,
wherein said resin comprises a base material and an insulating layer on the base material, wherein the insulating layer comprises the resin composition having components (A)-(D).

22. The laminate according to claim 19, obtained by heat-pressing one or more prepregs having an insulating layer, wherein the insulating layer comprising the resin composition having components (A)-(D) is on at least one surface of the prepreg.

23. A metal foil-clad laminate comprising a cured product of a prepreg with a resin layer, wherein one or more insulating layers each comprising a resin composition are on at least one surface of the prepreg; at least one of the insulating layers is an insulating layer comprising the resin composition defined by claim 1; and further a metal foil layer is on an outer side of the insulating layer.

24. The metal foil-clad laminate according to claim 23, wherein an outermost layer of the insulating layers is an insulating layer comprising the resin composition having components (A)-(D).

25. The metal foil-clad laminate according to claim 23, obtained by laying a resin sheet comprising a base material and an insulating layer on the base material, wherein the insulating layer comprises the resin composition having components (A)-(D), and comprising a metal foil as the base material, on at least one surface of the prepreg so that the insulating layer of the resin sheet faces the prepreg, and followed by heat-pressing.

26. The metal foil-clad laminate according to claim 23, obtained by laying a metal foil on at least one side of one prepreg with an insulating layer, said insulating layer of the prepeg comprising the resin composition having components (A)-(D) and is on at least one surface of the prepreg, or on a stack of two or more prepregs with an insulating layer, said prepegs having an insulating layer comprising the resin composition having components (A)-(D) and is on at least one surface of each prepreg, and followed by heat-pressing.

27. A multilayer printed wiring board comprising an inner layer circuit board and one or more insulating layers each comprising a resin composition, wherein the insulating layer or insulating layers are on an inner layer circuit pattern of the inner layer circuit board, and at least one of the insulating layers is an insulating layer comprising the resin composition defined by claim 1.

28. The multilayer printed wiring board according to claim 27, wherein, among the insulating layers, an outermost insulating layer with respect to the inner layer circuit pattern is an insulating layer comprising the resin composition having components (A)-(D).

29. The multilayer printed wiring board according to claim 27, obtained by laying a resin sheet comprising a base material and an insulating layer on the base material, wherein the insulating layer comprises the resin composition having components (A)-(D), on a surface of the inner layer circuit board, on which the inner layer circuit pattern is formed, and followed by heat-pressing.

30. The multilayer printed wiring board according to claim 27, obtained by laying a prepeg having an insulating layer, wherein the insulating layer comprises the resin composition having components (A)-(D) and is on at least one surface of the prepreg, on a surface of the inner layer circuit board, on which the inner layer circuit pattern is formed, and followed by heat-pressing.

31. A semiconductor device comprising the multilayer printed wiring board defined by claim 27 and a semiconductor element mounted on the multilayer printed wiring board.
